(19) United States
(12) Patent Application Publication
(10) Pub. No.: US 2004/0132398 A1
(43) Pub. Date: Jul. 8, 2004

(54) Integrated cabinet for containing electronic equipment

(76) Inventors: Anthony C. Sharp, Scarborough (CA); Michael J. Clarke, Willowdale (CA)

Correspondence Address: Mark G. Lappin, Esq., McDERMOTT, WILL & EMERY, 28 State Street, Boston, MA, 02109, US

(21) Appl. No.: 10/693,782

(22) Filed: Oct. 24, 2003

Related U.S. Application Data
(60) Provisional application No. 60/421,522, filed on Oct. 25, 2002.

(51) Int. Cl. H05K 5/00

(52) U.S. Cl. 454/184

(57) ABSTRACT

An integrated cabinet or a group of cabinets for supporting electronic equipment includes racks or other means for supporting the electronic equipment, heat management by liquid cooling, fire suppression systems, uninterruptible power supplies, power quality management, remote monitoring and control of cabinet parameters, such as temperature, humidity, intrusion, etc., a command center unit for connecting with and providing remote control and management of the electronic equipment contained within the cabinet(s), EMC/RFI/EMI containment and filters, seismic construction to comply with earthquake resistance standards, and acoustic noise control system.

### CROSS-REFERENCE TO RELATED APPLICATION

The present application claims priority to provisional U.S. patent application serial No. 60/421,522 filed Oct. 25, 2002, which is incorporated herein by reference.

### FIELD OF THE INVENTION

The present invention relates to cabinets for containing electronic equipment, such as computers, data servers, storage systems, communication systems, or other, similar equipment. In particular, the present invention relates to an integrated, stand-alone cabinet or group of cabinets for supporting electronic equipment a cooling system, a fire suppression system, an uninterruptible power supply, a power quality management system, a system for remote monitoring and control of cabinet parameters, a command center unit for connecting with and providing remote control and management of the electronic equipment contained within the cabinet(s), EMC/RFI/EMI containment and filters, seismic construction to comply with earthquake resistance standards, and acoustic noise control.

### BACKGROUND OF THE INVENTION

Data or server cabinets are used for containing, storing and protecting electronic equipment, such as computers, data servers, storage systems, communication systems, or other, similar equipment. Such cabinets are manufactured, for example, by the Enclosure Systems Group of the assignee of the present application, Sanmina-SCI Corporation (http://www.sanmina.com) of San Hose, Calif.

Such electronic storage cabinets can become extremely warm during operation of the electronic equipment contained therein. As an example, the advent of “high-density electronic data servers” has led to the mounting of as many as forty-two (42) servers in one cabinet. This in turn has greatly increased the total heat load in such cabinets, reaching as high as thirty (30) kilowatts, with attendant problems of maintaining acceptable working temperatures inside the cabinet. Without acceptable working temperatures, the life and reliability of the servers are reduced. Since these servers commonly handle large amounts of sensitive and valuable data, uncontrolled working temperatures are not acceptable, and steps to maintain the servers at a relatively cool and steady temperature are required.

One existing method of cooling server cabinets is to install a plurality of the cabinets in rooms that are air conditioned and/or supplied with ducted, cooled air. There are, however, several disadvantages to this method. To begin with, energy is wasted since the whole room and the contents of the room must be cooled. In addition, because the cabinets are mounted in rows, the heated air which exits one row of cabinets adversely affects the temperature of adjacent rows of cabinets. Furthermore, upgrading existing installations by the addition of cabinets filled with high density servers may not be possible since the cooling capacity of existing room air-conditioning units may be exceeded. Also, with the shortages of available electrical power, the demand of new room air-conditioner systems may not be met by the public utility. Finally, floor-standing heat management units are sometimes provided in such rooms for cooling the air delivered to the cabinets. Such units, however, occupy valuable floor area that could be more profitably occupied by a server cabinet.

Such cabinet storage rooms can also include other support systems shared by all of the cabinets of the room or applied “room-wide” including fire suppression systems, uninterruptible power supply systems, power quality management systems, systems for remote monitoring and control of cabinet parameters, such as temperature, humidity, intrusion, etc., a command center unit for connecting with and providing remote control and management of the electronic equipment contained within the cabinets, room-wide or shared EMC/RFI/EMI containment and filters, and room-wide acoustic noise control.

Again, however, there are disadvantages to all of the cabinets of the room sharing such support systems. To begin with, energy is wasted since the support systems are applied to the whole room and the contents of the room. In addition, upgrading existing installations by the addition of cabinets filled with high density electronic components may not be possible since the capacity of existing room support systems may be exceeded. Also, such separate support units occupy valuable floor area that could be more profitably occupied by an additional storage cabinet.

What is still desired, therefore, is a new and improved cabinet for containing electronic equipment, such as computers, data servers, storage systems, communication systems, or other, similar equipment. Preferably, the new and improved cabinet will comprise an integrated, stand-alone cabinet or group of cabinets for supporting electronic equipment and include racks or other means for supporting the electronic equipment and at least three of the following features: heat management by liquid cooling, fire suppression systems, uninterruptible power supplies, and power quality management. The new and improved cabinet may also include remote monitoring and control of cabinet parameters, such as temperature, humidity, intrusion, etc., a command center unit for connecting with and providing remote control and management of the electronic equipment contained within the cabinet(s), EMC/RFI/EMI containment and filters, seismic construction to comply with earthquake resistance standards, and acoustic noise control.

### SUMMARY OF THE INVENTION

In response, exemplary embodiments of the present invention provide an integrated, stand-alone cabinet or group of cabinets for supporting electronic equipment and including racks or other means for supporting the electronic equipment, heat management by liquid cooling, fire suppression systems, uninterruptible power supplies, power quality management, remote monitoring and control of cabinet parameters, such as temperature, humidity, intrusion, etc., a command center unit for connecting with and providing remote control and management of the electronic equipment contained within the cabinet(s), EMC/RFI/EMI containment and filters, seismic construction to comply with earthquake resistance standards, and acoustic noise control.

The foregoing and other features, aspects and advantages of the present invention will become more apparent from the following detailed description of the present invention when taken in conjunction with the accompanying drawings.

### BRIEF DESCRIPTION OF THE DRAWINGS

FIG. 1 is a front/side perspective view of an exemplary embodiment of a cabinet constructed in accordance with the present invention, for containing electronic equipment, such as computers, data servers, storage systems, communication systems, or other, similar equipment;

FIG. 2 is a front/side perspective view of an exemplary embodiment of a plurality of cabinets constructed in accordance with the present invention and connected together, for containing electronic equipment, such as computers, data servers, storage systems, communication systems, or other, similar equipment, and wherein a front panel of one of the cabinets is shown open to reveal an air flow distribution device;

FIG. 3 is a side sectional view of an exemplary embodiment of a system for removing heat from a plurality of electronic assemblies for use as part of an integrated cabinet, such as the cabinets of FIGS. 1 and 2;

FIG. 4 is a front elevation view of the system of FIG. 3, with a front panel of the cabinet removed to reveal an air flow distribution device of the cabinet;

FIG. 5 is a rear elevation view of a front panel and another exemplary embodiment of an air flow distribution device for use as part of an integrated cabinet, such as the cabinets of FIGS. 1 and 2;

FIG. 6 is a side elevation view of the front panel and the air flow distribution device of FIG. 5; and

FIG. 7 shows photographs of components of a fire detection and suppression system for use as part of an integrated cabinet, such as the cabinets of FIGS. 1 and 2.

Like reference characters designate identical or corresponding components and units throughout the several views.

### DETAILED DESCRIPTION OF THE INVENTION

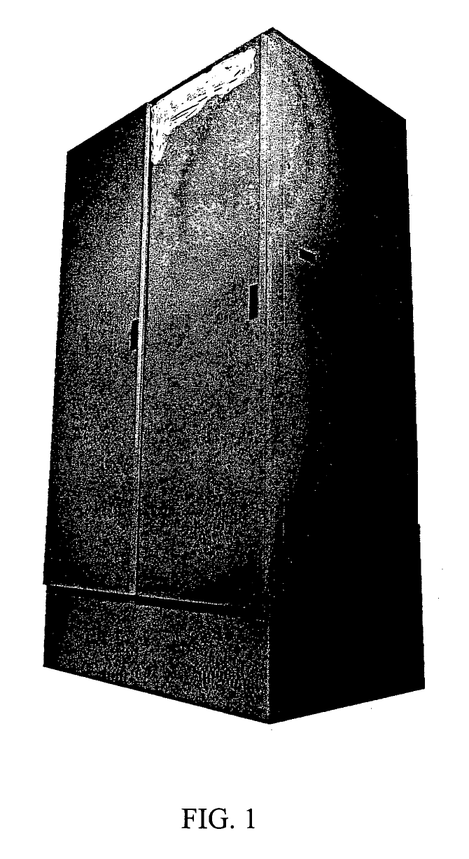

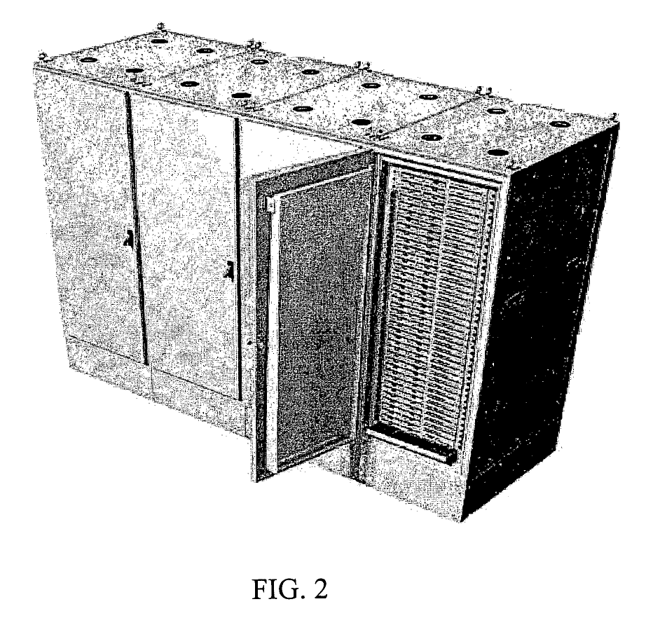

Referring to FIGS. 1 and 2, the present disclosure provides an integrated, stand-alone cabinet or group of cabinets for supporting electronic equipment. The cabinet of FIG. 1 contains a liquid cooling system, an airflow distribution device, a fire suppression system, an uninterruptible power supply system, a power quality management system, a cabinet remote monitoring and control system, a remote control and management system for the electronic equipment contained within the cabinets, an EMC/RFI/EMI containment and filter system, and an acoustic noise control system. At least one of the cabinets of FIG. 2 contains a liquid cooling system, an airflow distribution device, a fire suppression system, an uninterruptible power supply system, a power quality management system, a cabinet remote monitoring and control system, a remote control and management system for the electronic equipment contained within the cabinets, an EMC/RFI/EMI containment and filter system, and an acoustic noise control system.

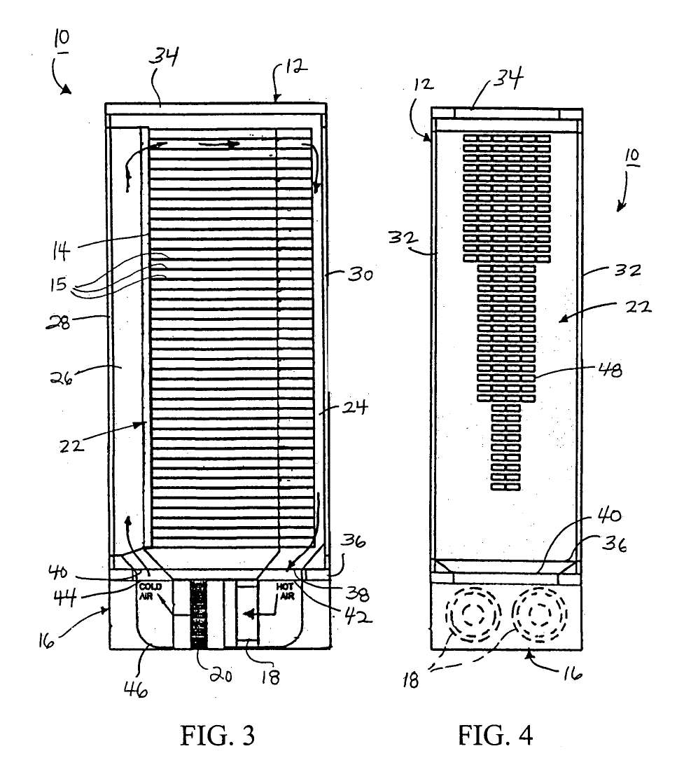

Referring to FIGS. 3 and 4, a system 10 constructed in accordance with the present invention can include, for example, at least one cabinet 12 containing means 14 for supporting electronic assemblies such as data servers, at least one plinth 16 containing means 18 for creating an airflow through the cabinet 12 and means 20 for removing heat from the airflow, and at least one air flow distribution device 22 for establishing a predetermined flow rate distribution through the cabinet 12.

Typical applications for the presently disclosed system 10 are found in “data centers” that contain hundreds of cabinets containing “servers” or other electronic data equipment. The equipment may, for example, be used for telecommunication purposes or for high speed internet or streaming data services. In the embodiment shown, the means for supporting the electronic assemblies comprise brackets 14 arranged to support the assemblies in a vertical array and wherein housings of the electronic assemblies will create separate horizontal passages in the vertical array. For purposes of illustration, the server housings are represented by horizontal lines 15 extending between the brackets 14. The “brackets” 14 generally comprise vertical metal strips that have spaced-apart mounting holes for the servers, etc. The servers normally are equipped with mounting brackets at or near their front faces which are fastened to the “brackets” 14 with screws. The means 14 for supporting the electronic assemblies in a vertical array can alternatively comprise shelves or other suitable hardware.

The cabinet 12 of the present disclosure includes the brackets 14 for supporting electronic assemblies in the vertical array 15 between a first vertical airflow path 24 and a second vertical air flow path 26 of the cabinet. The cabinet 12 is enclosed about the brackets 14 and the vertical airflow paths 24, 26 and includes front and rear panels 28, 30, side panels 32, and a top panel 34. The front and rear panels 28, 30 can be attached to the cabinet 12 with hinges to act as doors and provide access to electronic components supported on the brackets 14. A base 36 of the cabinet 12 defines an outlet 38 for the first vertical airflow path 24 and an inlet 40 for the second vertical airflow path 26. Other than the inlet 40 and the outlet 38 defined by the base 36, the cabinet 12 is closed such that the airflow through the cabinet is re-circulated.

The plinth 16 underlying the cabinet 12 has an input port 42 receiving air from the outlet 38 of the first vertical airflow path 24 of the cabinet, an output port 44 transmitting air from the plinth to the inlet 40 of the second vertical air flow path 26 of the cabinet, and a plinth air flow path 46 extending between the input and the output ports. At least one heat exchanger 20 is positioned in the plinth air flow path 46 for transferring heat to a heat exchange medium passing through the heat exchanger 20, and at least one fan assembly 18 is disposed along the plinth air flow path 46 for driving air through the heat exchanger 20 and the cabinet 12. The heat exchanger 20 preferably comprises coils that receive liquid coolant for circulation from a remote source. Heat from the airflow received from the cabinet 12 is absorbed by coolant in the coils 20. Preferably, the coolant comprises cool water, but can also comprise refrigerant fluids.

To achieve the high reliability desired for the system 10, redundancy of essential operating components is preferably employed. Thus, multiple fans 18 are used, so that failure of one fan does not cause total failure of the system 10. Similarly, the heat exchanger 20 preferably comprises multiple chilling coils. Furthermore, the fans 18 and the heat exchanger 20 are constructed and mounted in such a way as to facilitate rapid withdrawal and replacement, for instance on sliding drawers. Remote signaling of alarm conditions, such as fan failure, or high temperature conditions, will facilitate prompt attention by maintenance staff, thus improving overall reliability. To further enhance the rapid servicing of the essential operating components, quick-disconnect means may be employed, for instance the water connections may be made by means of the well-known “double-shutoff” hydraulic hose couplers, and the electrical connections by shrouded plugs and sockets.

In one embodiment of the present disclosure, the plinth 16 can be sized to support multiple cabinets 12. In another embodiment, the plinth 16 may contain one chilling coil 20 for each cabinet 12 mounted on the plinth, one for two or more cabinets, or one for all cabinets mounted upon the plinth. In an alternative embodiment, the plinth 16 may contain one fan 18, or several fans for the movement of air. In a further embodiment, multiple plinths 16 may be used to support and cool a single cabinet 12. In yet another embodiment, side-by-side cabinets 12 and plinths 16 may be bolted together to provide greater resistance to seismic activity. Many combinations and arrangements are possible without departing from the scope of the present invention.

In any event, the modular arrangement of the plinth 16 and the cabinet 12 makes the system 10 versatile and provides improved energy efficiency in comparison to cooling an entire room full of cabinets. The present system 10, thus, reduces running costs and enables larger installations with a given power availability. In addition, by placing the heat removal means in close conjunction with the servers, a better control of the heat removal may be achieved, and, since the temperature may be better regulated, the life and reliability of the servers may be enhanced.

Because the plinth 16 has substantially the same “footprint” dimensions as the cabinet 12, valuable floor area within a server room or installation is made available. Also, by keeping the water-containing parts of the system 10 in the plinth 16, beneath the cabinet 12, the effects of any coolant leak are greatly minimized. Finally, since the specific heat of water and the density of water (or other suitable liquid coolant) are much higher than air, water is a much better medium for moving heat from the cabinet 12, as compared to just air.

Still referring to FIGS. 3 and 4, the air flow distribution device 22 of the system 10 is for establishing a predetermined flow rate distribution through various electronic assemblies supported by the brackets 14. In the embodiment shown, the device 22 is configured such that the predetermined flow rate distribution is substantially the same. In other words, the device 22 apportions cooling airflow from the second airflow path 26 of the cabinet 12 approximately equally amongst electronic assemblies supported by the brackets 14, so that each data server held therein is cooled by the same amount of air. However, it should be understood that the device 22 can be configured such that the predetermined flow rate distribution varies, to accommodate different types or sizes of data servers (which might provide different heat loads) for example.

As shown, the distribution device 22 is positioned between the second air flow path 26 of the cabinet 12 and the brackets 14. However, the distribution device 22 can alternatively be positioned between the brackets 14 and the first airflow path 24 of the cabinet. In addition, the cabinet 12 can be provided with two of the distribution devices 22, one positioned between the second air flow path 26 of the cabinet and the brackets 14 and the other positioned between the brackets and the first airflow path 24 of the cabinet.

The distribution device 22 is substantially planar and extends vertically, and includes a plurality of apertures 48 in a predetermined pattern of sizes and positions. As shown in FIG. 2, the apertures 48 of the distribution device 22 at different distances from the plinth 16 are sized and positioned to apportion airflow from the second airflow path 26 of the cabinet approximately equally amongst the brackets 14. In particular, the apertures 48 are equally sized and provided in horizontal rows corresponding to the brackets 14, and the horizontal rows closest to the plinth 16 include fewer apertures 48 than the horizontal rows furthest from the plinth (if appropriate to the desired flow rate distribution, however, the horizontal rows closest to the plinth 16 can be provided with more apertures 48 than the horizontal rows furthest from the plinth).

The distribution device 22 can alternatively be provided with a plurality of apertures, wherein the apertures are provided in horizontal rows, each row includes the same number of apertures, but the sizes of the apertures increase further from the plinth 16 (if appropriate to the desired flow rate distribution, however, the sizes of the apertures can be provided as decreasing further from the plinth 16). The distribution device 22 can alternatively be provided with aperture in horizontal rows, wherein the numbers of apertures in each row and the sizes of the apertures both increase further from the plinth 16 (if appropriate to the desired flow rate distribution, however, the numbers of apertures in each row and the sizes of the apertures can both be provided as decreasing further from the plinth 16).

Thus, the predetermined pattern of sizes and positions of the apertures can be varied to provide a desired flow rate distribution without departing from the scope of the present invention. Although not shown, the apertures 48 can also be provided with louvers to help direct airflow from the vertical airflow path 29 in a horizontal direction through electronic devices supported by the brackets 14.

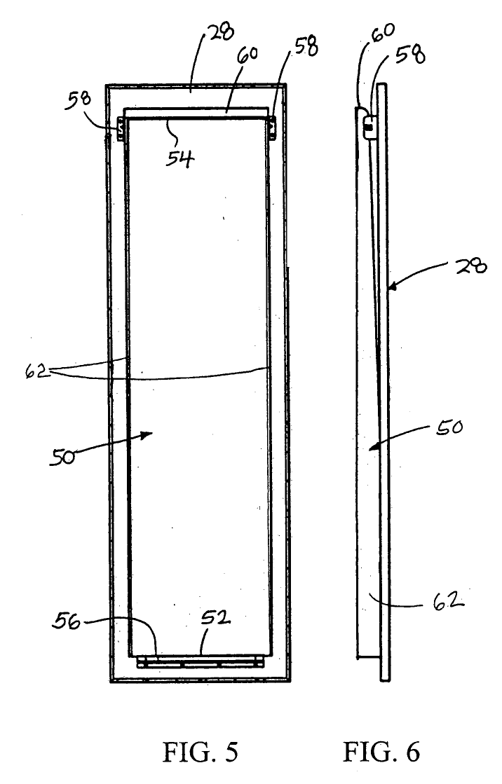

Referring now to FIGS. 5 and 6, another exemplary embodiment of an air flow distribution device 50 for use as part of an integrated cabinet, such as the cabinets of FIGS. 1 and 2, is shown. This distribution device 50 is for use with the system 10 of FIGS. 3 and 4 in place of the distribution device 22. When assembled to the cabinet 12, the distribution device 50 of FIG. 5 and 6 extends vertically and laterally within the second airflow path 26 between a lower end 52 nearer the plinth 16 and an upper end 54 further from the plinth 16, such that the upper end 54 of the distribution device is closer to the brackets 14 than the lower end 52. In the embodiment shown, the device 50 is substantially planar. In this manner, the device 50 reduces the cross-sectional area of the second air flow path 26 further from the plinth 16, to apportion airflow from the second airflow path 26 of the cabinet 12 approximately equally amongst electronic devices supported by the brackets 14.

It should be understood, that the device 50 can be configured to be curved, or otherwise formed, instead of planar, so as provide a varied airflow distribution. In addition, the device 50 can be positioned in the first airflow path 24 of the cabinet 12 instead of the second airflow path 26. Furthermore, the cabinet 12 can be provided with two of the distribution devices 50, one positioned in the second air flow path 26 and the other positioned in the first airflow path 24 of the cabinet.

In the exemplary embodiment of FIGS. 5 and 6, the distribution device 50 is mounted to the inside of the front panel 28 of the cabinet 28. As shown, the lower end 52 is secured to the panel 28 with a hinged assembly 56, while the upper end 54 is adjustably secured to the panel with brackets 58, such that the position of the upper end with respect to the brackets 14 can be adjusted. Preferably, the device 50 is provided with a hood 60 at the upper end extending towards the brackets 14 and side plates 62 extending downwardly from the hood for helping to direct airflow towards the brackets. The side plates 62 are configured such that edges 64 of the side plates 62 extend vertically and parallel with the panel 28. Although not shown, the distribution device 50, the hood 60, and the side plates 62 are preferably sized and positioned within the cabinet such that a substantially enclosed duct is formed between the distribution device 50 and the vertical array of servers.

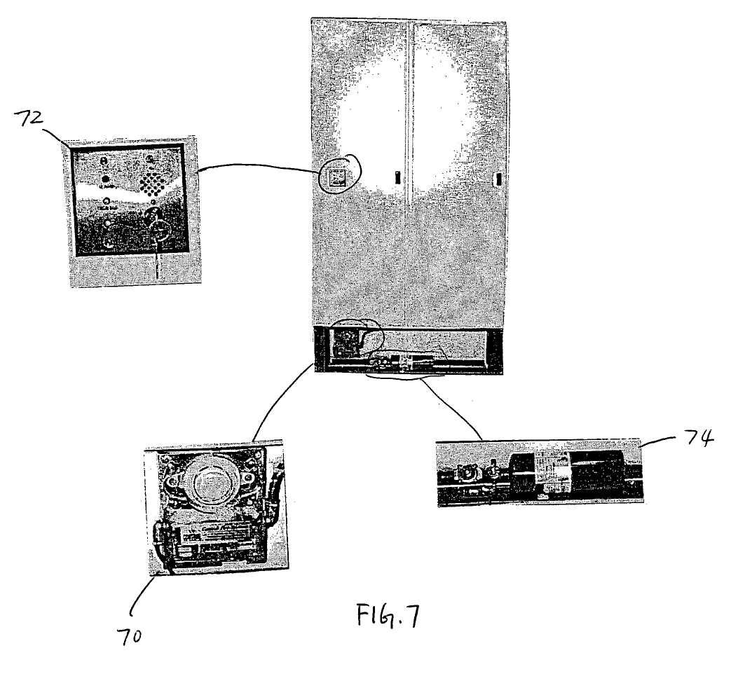

FIG. 7 shows photographs of components of a fire detection and suppression system for use as part of an integrated cabinet, such as the cabinets of FIGS. 1 and 2. As shown, the system can include a proactive smoke detector 70 (e.g., Photoelectric or Ionization detector), an integrated control panel 72 (e.g., including an annunciator, a solenoid release, a main panel relay), a container 74 containing FM-200 Clean Agent, or inert gas proven suppression agents, spray nozzles, an optional back-up cylinder, and manual and electric discharge mechanisms. The smoke detector 70 preferably is photoelectric detector using infrared beams to detect smoke. The control panel 72 preferably includes two LED's, a green LED indicative a “normal” state when it is “on”, and a red LED indicative an “alarm” state when it is “on”.

Although not shown, the cabinets of FIGS. 1 and 2 also include integrated systems for remotely monitoring and controlling the temperature, humidity, and airflow in the cabinets to ensure proper operating conditions. The system can also watch power supply voltages for spikes and dips that may damage hardware components, keeps a historical log if required, ensure that door latches and covers are correctly closed, and monitor and log personnel access into secure areas.

Although not shown, the cabinets of FIGS. 1 and 2 also include integrated uninterruptible power supply systems, power quality management systems, remote control and management systems for the electronic equipment contained within the cabinets, EMC/RFI/EMI containment and filter systems, and acoustic noise control systems.

The cabinets of FIGS. 1 and 2 are preferably also designed to meet minimum standards for earthquake resistance, such as the BELLCORE Zone 4 seismic test set forth in Document # GR-63-CORE.

The present invention, therefore, relates to cabinets for data equipment, such as servers, computers, storage systems, and communications equipment. It comprises a data cabinet with all, or some (as determined by the data requirements) of the following equipment and features integrated within a single cabinet, or a multiplicity of cabinets: Space for servers etc. May be c/w visibility through transparent doors; heat management by liquid cooling, optionally including refrigerant fluids; fire suppression by monitoring, control and discharge of suppressant within the cabinet; UPS (uninterruptible power supplies); power quality management; remote monitoring and control of cabinet parameters, such as temperature, humidity, intrusion, etc. optionally via the Internet; a command center with remote control and management of the data equipment; EMC/RFI containment/rejection built-in; seismic construction to withstand earthquakes; and acoustic noise control.

The features listed have heretofore been supplied by external means, or been selectively integrated within cabinets, but not fully integrated, as is now described, to embody a complete Integrated Data Cabinet. Not all the above features may be required for a given Integrated Data Cabinet, but all those which are required in a given instance are integrated within the cabinet, or multiplicity of cabinets.

Among other features and advantages, the present invention provides a self-contained Integrated Data Cabinet, replacing those features typically offered in a traditional data center setting, capable of providing highly reliable, continuous service without data interruption. Thus, the Integrated Data Cabinet does not require separate construction and integration on-site of the desirable features; they can all be supplied from the factory ready to use, with attendant cost savings.

The present invention also offers the advantage of complete data center features within a cabinet, or cabinets, without the need for supporting infrastructure and services.

Although the present invention has been described and illustrated in detail, it is to be clearly understood that the same is by way of illustration and example only and is not to be taken by way of limitation, the scope of the present invention being limited only by the terms of the appended claim.

What is claimed is:

1. An integrated cabinet for supporting electronic equipment, comprising:
means for supporting electronic assemblies disposed inside the cabinet;
a cooling system including an air flow path extending within the cabinet, and a heat exchanger disposed within the air flow path for transferring heat from air passing through the air flow path to a liquid cooling medium passing through the heat exchanger;
a fire detecting system, for detecting at least one of heat and smoke, operatively connected to the cabinet for providing a signal upon detecting heat or smoke;
a fire suppression system operatively connected to the fire detecting system, for discharging fire suppressant into the cabinet in response to a signal being provided by the fire detecting system;
an uninterruptible power supply system for powering the electronic equipment supported within the cabinet; and
a remote monitoring system having at least one sensor disposed within the cabinet and a monitoring station disposed remote to the cabinet, the remote monitoring station being operatively connected to the at least one sensor, and being adapted for receiving signals from the at least one sensor.

2. An integrated cabinet for supporting electronic equipment according to claim 1, wherein the sensor of the remote monitoring system comprises a temperature sensor.

3. An integrated cabinet for supporting electronic equipment according to claim 2, wherein the remote monitoring system is operatively connected to the cooling system, the remote monitoring system being adapted to control the cooling system to adjust the temperature inside the cabinet responsive to the temperature sensor.

4. An integrated cabinet for supporting electronic equipment according to claim 1, wherein the sensor of the remote monitoring system comprises a humidity sensor, the remote monitoring system being adapted to display signals indicative of the humidity inside the cabinet.

5. An integrated cabinet for supporting electronic equipment according to claim 4 further comprising a humidity control system disposed within the cabinet and being operatively connected to the remote monitoring system, the remote monitoring system adapted to control the humidity control system to adjust the humidity inside the cabinet responsive to the humidity sensor.

6. An integrated cabinet for supporting electronic equipment according to claim 1 further comprising at least one sensor disposed within the cabinet for detecting intrusion of the cabinet.

7. An integrated cabinet for supporting electronic equipment according to claim 1, wherein the liquid cooling medium is water.

8. An integrated cabinet for supporting electronic equipment according to claim 1, wherein the liquid cooling medium is refrigerant fluid.

9. An integrated cabinet for supporting electronic equipment according to claim 1 further comprising power quality management system for managing the power supply of the electronic equipment supported by the cabinet.

10. An integrated cabinet for supporting electronic equipment according to claim 1, wherein the cabinet is characterized by a seismic resistance structure.

11. An integrated cabinet for supporting electronic equipment according to claim 1 further comprising an EMC/RFI/EMI containment and filter system disposed within the cabinet.

12. An integrated cabinet for supporting electronic equipment according to claim 1 further comprising a remote control system operatively coupled to the cabinet for controlling at least one predetermined type of parameter of an interior environment within the cabinet.

13. An integrated cabinet for supporting electronic equipment according to claim 12, wherein the at least one predetermined type of parameter comprises temperature and/or humidity.

14. An integrated cabinet for supporting electronic equipment according to claim 1, wherein the fire suppressant of the fire suppression system comprises an inert gas.

15. An integrated cabinet for supporting electronic equipment according to claim 1 further comprising a remote data management system for managing the electronic equipment contained within the cabinet.

16. An integrated cabinet for supporting electronic equipment according to claim 1 further comprising a control panel operatively connected to the fire detection system and mounted on the cabinet, for providing an alarm in response to a signal being provided by the fire detecting system.

17. An integrated cabinet for supporting electronic equipment according to claim 1 further comprising an acoustic noise control system disposed within the cabinet.

18. An integrated cabinet for supporting electronic equipment according to claim 1, wherein the fire detecting system comprises a photoelectric detector.

19. An integrated cabinet for supporting electronic equipment according to claim 1, wherein the fire detecting system comprises an ionization detector.

20. An electronic equipment system comprising a plurality of connected cabinets of claim 1.
